(19) United States
(12) Patent Application Publication
(10) Pub. No.: US 2019/0288643 A1
(43) Pub. Date: Sep. 19, 2019

(54) ARC DETECTING APPARATUS AND CONTROL METHOD THEREOF, AND NON-TRANSITORY COMPUTER READABLE RECORDING MEDIUM

(71) Applicant: OMRON Corporation, Kyoto (JP)

(72) Inventors: Satoru IKEMOTO, Kyoto-shi (JP); Kohei TOMITA, Kyoto-shi (JP); Naoki MAKI, Kyoto-shi (JP); Takayuki KUROKI, Kyoto-shi (JP)

(73) Assignee: OMRON Corporation, Kyoto (JP)

(21) Appl. No.: 16/251,101

(22) Filed: Jan. 18, 2019

(30) Foreign Application Priority Data
Mar. 14, 2018 (JP) 2018-047192

(51) Int. Cl. H02S 50/10; G01R 31/08; G01R 31/12

(52) U.S. Cl. CPC H02S 50/10; G01R 31/1227; G01R 31/083

(57) ABSTRACT

In the disclosure, the occurrence of an arc is rapidly detected while the frequency of erroneous detection is suppressed. An arc detecting apparatus includes an arc presence/absence determining part determining presence or absence of an arc based on an AC current measured by a current sensor measuring a current from a solar cell, and a repeat number setting part setting, based on a signal strength of the AC current, a repeat number of processing that the arc presence/absence determining part repeatedly performs to determine the presence or absence of the arc.

### CROSS-REFERENCE TO RELATED APPLICATION

This application claims the priority of Japan patent application serial no. 2018-047192, filed on Mar. 14, 2018. The entirety of the above-mentioned patent application is hereby incorporated by reference herein and made a part of this specification.

### BACKGROUND

### Technical Field

The disclosure relates to an arc detecting apparatus applied to a DC power system, such as a solar power system, a control method thereof, and a control program.

### Description of Related Art

Conventionally, in a solar power system, the power generated by a solar cell is supplied to a power transmission network via a power conditioning system (hereinafter simply referred to as PCS) including a DC/AC converter, etc. In such a solar power system, an arc may be generated due to a failure of a circuit, etc., in the system. In the case where an arc is generated, the temperature at the portion where the arc is generated becomes high, and there is a risk of causing a fire, etc. Therefore, the solar power system includes an arc detecting apparatus that detects the occurrence of an arc by measuring the AC current of the arc with a current sensor.

In the arc detecting apparatus described in Patent Document 1 (Japanese Laid-Open No. 2016-151514), firstly, the output current of a solar cell string is detected by a current sensor, and the detected output current is converted into a power spectrum. Next, with respect to the power spectrum of a measuring interval of the arc, which is a predetermined frequency range, the measuring interval is divided into a plurality of domains, and any of the domain values, which are the magnitudes of the power spectrum of the respective domains, excluding the maximum domain value is acquired to serve as the interval value of the measuring interval. Then, the interval value is compared with a threshold to determine the presence or absence of an arc.

As described above, when an arc occurs, there is a risk of causing a fire, etc., so it is desired to quickly detect the occurrence of the arc. In order to quickly detect the occurrence of the arc, for example, it is conceivable to lower the threshold.

However, in this case, the frequency that the noise other than the arc (for example, the switching noise of the PCS, etc.) is erroneously determined as the noise of the arc, and the occurrence of the arc is erroneously detected is increased. The solar power system needs to be temporarily shut down for every detection or erroneous detection of the occurrence of the arc. Therefore, with the increased frequency of erroneous detection, the power generation efficiency decreases.

One aspect of the disclosure provides an arc detecting apparatus, etc., that is capable of quickly detecting the occurrence of the arc while suppressing the frequency of erroneous detection.

### SUMMARY

An arc detecting apparatus according to one aspect of the disclosure includes an arc determining part which determines presence or absence of an arc based on an AC current contained in a current from a DC power source that generates power or charges and discharges power, and a repeat number setting part which sets, based on a signal strength of the AC current, a repeat number of processing that the arc determining part repeatedly performs to determine the presence or absence of the arc.

Further, another aspect of the disclosure provides a control method of an arc detecting apparatus, which is a control method of an arc detecting apparatus that detects occurrence of an arc. The method includes: an arc determining step of determining presence or absence of an arc based on an AC current contained in a current from a DC power source that generates power or charges and discharges power; and a repeat number setting step of setting a repeat number of processing repeatedly performed to determine the presence or absence of the arc in the arc determination step based on a signal strength of the AC current.

An arc detecting apparatus according to one aspect of the disclosure may be realized by a computer; in this case, a control program of the arc detecting apparatus which causes the computer to realize the arc detecting apparatus by causing the computer to operate as each part included in the arc detecting apparatus, and a computer readable recording medium on which the control program is recorded are also within the scope of this disclosure.

### BRIEF DESCRIPTION OF THE DRAWINGS

FIG. 1 is a schematic circuit diagram showing an example of a configuration of a solar power system including an arc detecting apparatus according to an embodiment of the disclosure.

FIG. 2 is a block diagram showing an example of a configuration of the arc detecting apparatus.

FIG. 3(a) is a graph showing a time waveform of a current signal detected by a current sensor in the arc departing apparatus, and FIG. 3(b) is a graph showing a waveform of a power spectrum of a current signal generated by a CPU in the arc detecting apparatus.

FIG. 4 is a flowchart showing an example of the operation of the arc detecting apparatus.

FIG. 5 is a schematic circuit diagram showing a modified example of the solar power system.

FIG. 6 is a flowchart showing another example of the operation of the arc detecting apparatus.

FIG. 7 is a flowchart showing another example of the operation of the arc detecting apparatus.

FIG. 8 is a block diagram showing an example of the configuration of an arc detecting apparatus according to another embodiment of the disclosure.

FIG. 9 is a graph showing a temporal change in a current signal output from a filter in the arc detecting apparatus and a peak value output from a peak hold circuit in the arc detecting apparatus

FIG. 10 is a flowchart showing an example of the operation of the arc detecting apparatus.

### DESCRIPTION OF THE EMBODIMENTS

Hereinafter, embodiments according to one aspect of the disclosure (hereinafter also referred to as “this embodiment”) will be described with reference to the drawings.

### § 1 Application Example

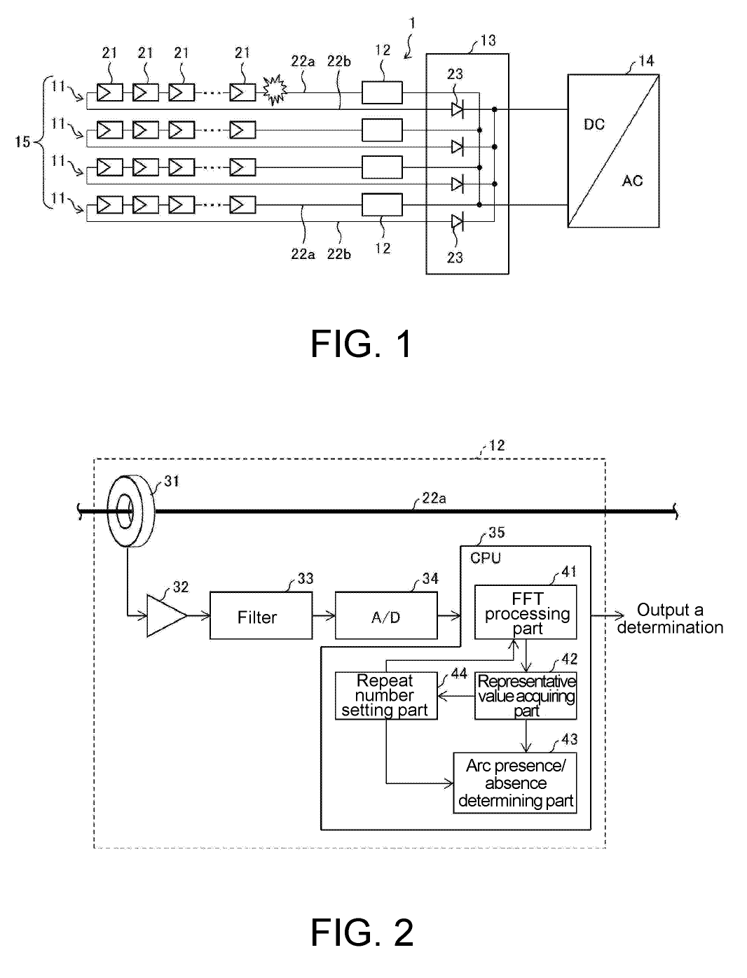

First, an example of a scenario to which the disclosure is applied will be described with reference to FIGS. 1 and 2.

FIG. 1 is a schematic circuit diagram showing an example of the configuration of a solar power system including an arc detecting apparatus according to this embodiment. As shown in FIG. 1, a solar power system 1 includes a plurality of solar cell strings 11, an arc detecting apparatus 12, a junction box 13, and a power conditioning system (hereinafter referred to as PCS) 14.

FIG. 2 is a block diagram showing an example of the configuration of the arc detecting apparatus 12. As shown in FIG. 2, the arc detecting apparatus 12 includes a current sensor 31 (current measuring part), an amplifier 32, a filter 33, an A/D converting part 34, and a central processing unit (CPU) 35.

As shown in FIG. 1 and FIG. 2, the arc detecting apparatus 12 includes the current sensor 31 for measuring a current from the solar cell string 11, an arc presence/absence determining part (arc determining part) 43 for determining the presence or absence of an arc based on the AC current measured by the current sensor 31, and a repeat number setting part 44 for setting, based on the signal strength of the AC current, the repeat number of the processing that the arc presence/absence determining part 43 repeatedly performs to determine the presence or absence of the arc.

According to this configuration, based on the signal strength of the AC current, the repeat number of the processing repeatedly performed to determine the presence or absence of the arc is set. For example, as the signal strength increases, the repeat number may be decreased. When the signal strength is high, the possibility of erroneously determining noise other than the arc as the noise of the arc is decreased. On the other hand, when the repeat number decreases, the possibility of erroneous determination increases, but the occurrence of the arc can be detected quickly. Therefore, the occurrence of the arc can be quickly detected while the possibility of erroneous determination can be suppressed. That is, the occurrence of the arc can be quickly detected while the frequency of erroneously detecting the occurrence of the arc can be suppressed.

If the signal strength is high, since the energy of the arc is strong, the risk of a fire, etc., due to the arc increases. Therefore, by using the arc detecting apparatus of this embodiment, the risk can be effectively reduced, and as a result, the solar power system 1 can be used safely.

As the signal strength decreases, the repeat number may be increased. If the signal strength decreases, the possibility that noise other than the arc is erroneously determined as the noise of the arc is increased. On the other hand, as the repeat number increases, even though the detection of the occurrence of the arc is delayed, the possibility of erroneous determination is decreased. Therefore, the possibility of erroneous determination can be suppressed, and the frequency of erroneously detecting the occurrence of the arc can be suppressed.

In addition, examples of the signal strength of the AC current include a power spectrum showing a signal strength with respect to frequency (first embodiment), an amplitude showing a signal strength with respect to time (second embodiment), etc.

### § 2 Configuration Example

Embodiments of the disclosure will be described with reference to FIGS. 1 to 8. For the convenience of description, the members shown in the respective embodiments and the members sharing the same functions therewith are denoted by the same reference numerals, and the description thereof is omitted as appropriate.

(Outline of Solar Power System)

As shown in FIG. 1, the solar cell string 11 (DC power source) is formed by connecting a plurality of solar cell modules 21 in series. Each solar cell module 21 includes a plurality of solar cells (not shown) connected in series, and is formed in a panel shape. The solar cell strings 11 constitute a solar cell array 15. Each solar cell string 11 is connected to the PCS 14 via the junction box 13.

The PCS 14 converts DC power input from each solar cell string 11 into AC power and outputs the AC power. In place of the PCS 14, a load apparatus that consumes the DC power may be provided.

The junction box 13 connects the solar cell strings 11 in parallel. In particular, output lines 22a connected to terminals of the respective solar cell strings 11 are connected to each other and output lines 22b connected to the other terminals of the respective solar cell strings 11 are connected to each other. It should be noted that a reverse flow preventing diode 23 is provided at the output line 22b.

In this embodiment, the arc detecting apparatus 12 is provided at the output line 22a of the solar cell string 11 for each solar cell string 11.

(Arc Detecting Apparatus 12)

As shown in FIG. 2, the current sensor 31 detects the current flowing through the output line 22a. The current sensor 31 is configured to include a current transformer (CT), for example. The amplifier 32 amplifies the current signal detected by the current sensor 31.

The filter 33 is a band pass filter (BPF), and allows only a current signal in a predetermined frequency range, among the AC current signals output from the amplifier 32, to pass through. In this embodiment, the frequency range that the filter 33 allows to pass through is 40 kHz to 100 kHz. In this way, the current signal of a frequency component (usually 40 kHz or less) including a large amount of switching noise of a converter (DC/DC converter) that the PCS 14 includes can be excluded from the current signals output from the amplifier 32.

The A/D converting part 34 converts the analog current signal passing through the filter 33 into a digital current signal and inputs the digital current signal to the CPU 35.

The CPU 35 performs FFT on the digital current signal input from the A/D converting part 34, and generates a power spectrum of the current signal. Further, the CPU 35 determines the presence or absence of occurrence of the arc based on the generated power spectrum. Then, the CPU 35 outputs the determination result to the outside.

This determination result is input to a control apparatus (not shown) of the solar power system 1, for example. When the determination result that the arc is present is input from the CPU 35, the control apparatus cuts off the circuit of the solar power system 1 to prevent a fire due to the arc or the damage of the solar power system 1.

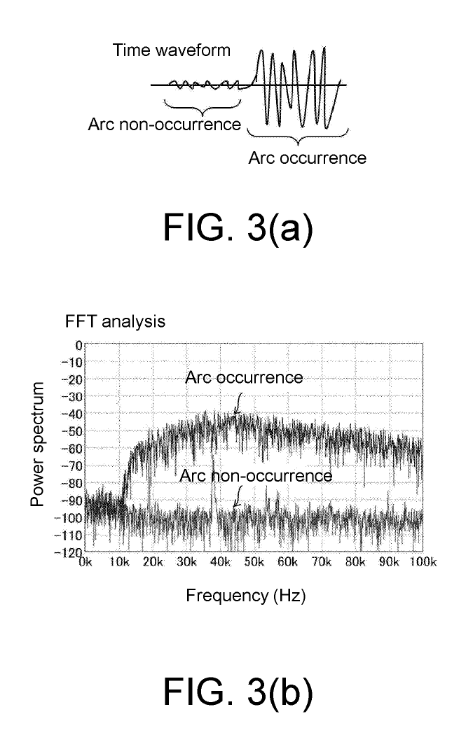

FIG. 3(a) is a graph showing a time waveform of the current signal detected by the current sensor 31, and FIG. 3(b) is a graph showing a waveform of the power spectrum of the current signal generated by the CPU 35. In FIGS. 3(a) and 3(b), the waveforms in both arc occurrence and arc non-occurrence states are shown.

In the case where the arc does not occur in the solar cell string 11, the waveform of the current signal is formed as the waveform of the arc non-occurrence state as shown in FIG. 3(a), and the waveform of the power spectrum of the current signal is formed as the waveform of the arc non-occurrence state as shown in FIG. 3(b). On the other hand, in the case where the arc occurs in the solar cell string 11, the waveform of the current signal is formed as the waveform of the arc occurrence state as shown in FIG. 3(a), and the waveform of the power spectrum of the current signal is formed as the waveform of the arc occurrence state as shown in FIG. 3(b).

Referring to FIGS. 3(a) and 3(b), it can be understood that, compared with the arc non-occurrence state, the amplitude of the current signal increases and the level of the power spectrum of the AC current signal increases in the arc occurrence state. Therefore, based on the high frequency component of the current signal detected by the current sensor 31, the arc detecting apparatus 12 can detect the occurrence of the arc in the solar cell string 11.

(CPU 35)

As shown in FIG. 2, the CPU 35 has an FFT processing part 41, a representative value acquiring part 42, the arc presence/absence determining part 43 and the repeat number setting part 44.

The FFT processing part 41 captures the digital current signal input from the A/D converting part 34, repeats the capturing multiple times, performs FFT processing on the captured current signal set, so as to generate the power spectrum of the current signal. The FFT processing part 41 provides the power spectrum of the generated current signals to the representative value acquiring part 42.

The representative value acquiring part 42 acquires the representative value of the power spectrum of the current signal based on the power spectrum of the current signal from the

FFT processing part 41. The representative value acquiring part 42 provides the acquired representative value to the arc presence/absence determining part 43 and the repeat number setting part 44.

As the representative value, various types can be considered. For example, the representative value may be a statistical value, such as an average value, a maximum value, a minimum value, a median value, a mode value, etc., of the power spectrum at the predetermined measuring interval (for example, 40 kHz to 80 kHz). In addition, the representative value may be a value obtained by integrating the power spectrum over the measuring interval.

Further, as described in Patent Document 1, with respect to the power spectrum of the measuring interval of the arc, the measuring interval is divided into a plurality of domains, and any of the domain values, which are the magnitudes of the power spectrum of the respective domains, excluding the maximum domain value may be acquired as the interval value of the measuring interval, and the acquired interval value may be the representative value. Also, in addition to acquiring the interval value of the measuring interval of the arc, the interval value with respect to the power spectrum of the measuring interval of the noise in a frequency range different from the measuring interval of the arc may be acquired, and the ratio or the difference between the interval value of the measuring interval of the arc and the interval value of the measuring interval of the noise may serve as the representative value.

The arc presence/absence determining part 43 uses a representative value S acquired by the representative value acquiring part 42 to determine the presence or absence of the arc. The arc presence/absence determining part 43 outputs the determination result to the outside.

Specifically, the arc presence/absence determining part 43 compares the representative value S acquired by the representative value acquiring part 42 with a predetermined threshold K, and determines whether the representative value S is greater than the threshold K. As a result of this determination, the arc presence/absence determining part 43 makes a temporary determination that the arc is present if the representative value S is greater than the threshold K, and makes a temporary determination that the arc is absent if the representative value S is less than or equal to the threshold K.

It should be noted that the threshold K can be easily determined by repeatedly performing the operation of determining the presence or absence of the arc. That is, excessive trial-and-errors are unnecessary for determining the threshold K.

The processing (temporary determination processing) of the FFT processing part 41, the representative value acquiring part 42 and the arc presence/absence determining part 43 are repeated for a plurality of times, and in the case where the number of times of the temporary determination process is within a certain number of times, if the determination result that the arc is present exceeds a certain number of times, the arc presence/absence determining part 43 outputs a final determination result that the arc is present to the outside.

This final determination result is input to a control apparatus (not shown) of the solar power system 1, for example. With the final determination result that the arc is present being from the arc presence/absence determining part 43, the control apparatus cuts off the circuit of the solar power system 1, so as to prevent a fire due to the arc or the damage of the solar power system 1.

Based on the representative value from the representative value acquiring part 42, the repeat number setting part 44 sets the repeat number in the repeated processing performed in the FFT processing part 41 or the arc presence/absence determining part 43. The repeat number setting part 44 provides the determined repeat number to the FFT processing part 41 or the arc presence/absence determining part 43.

As a result, for example, the FFT processing part 41 repeats capturing of data for the number of times of the repeat number set by the repeat number setting part 44. Alternatively, the arc presence/absence determining part 43 repeats the temporary determination processing for the number of times of the repeat number. Alternatively, the arc presence/absence determining part 43 outputs the final determination result that the arc is present to the outside when the temporary determination result that the arc is present repeats the number of times of the repeat number.

(Operation of Arc Detecting Apparatus 12)

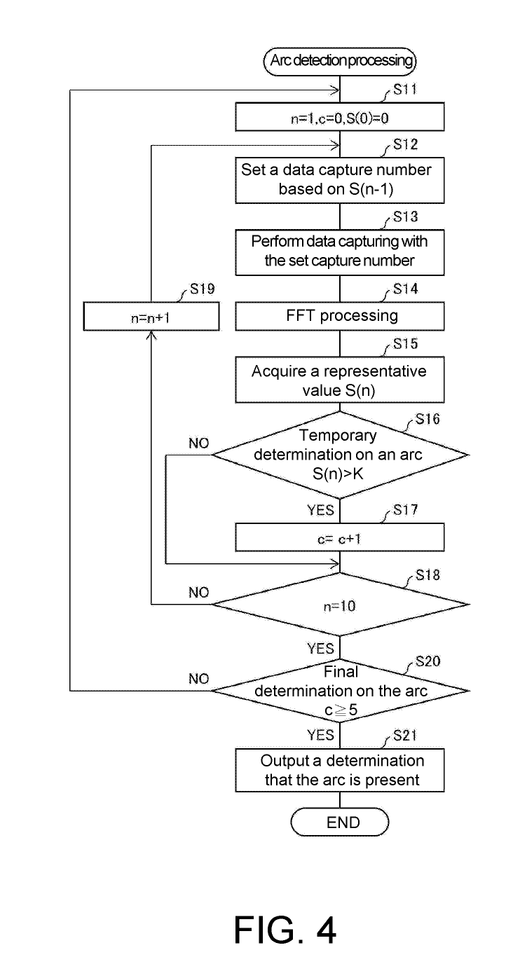

FIG. 4 is a flowchart showing an example of the operation of the arc detecting apparatus 12 having the above configuration. In FIG. 4, the FFT processing part 41 repeatedly captures data for the number of times of the repeat number set by the repeat number setting part 44.

First, as shown in FIG. 4, in arc detection, the arc presence/absence determining part 43 respectively resets a counter n to an initial value 1 and a counter c to an initial value 0, and the repeat number setting part 44 resets the representative value S to an initial value S(0)=0 (S11). Incidentally, the counter n is a counter for counting the number of times of determination of the arc, and the counter c is a counter for counting the number of times that the arc is determined as present in the arc determination result.

Next, the repeat number setting part 44 sets a capture number Ndata of data based on the previous (n−1) representative value S(n−1) acquired by the representative value acquiring part 42 (S12). For example, in the case where the representative value S(n−1) is less than 10, the capture number Ndata is determined to be 8192. Further, in the case where the representative value S(n−1) is equal to or more than 10 and less than 30, the capture number Ndata is determined to be 4096. Further, in the case where the representative value S(n−1) is equal to or more than 30 and less than 100, the capture number Ndata is determined to be 2048. Further, in the case where the representative value S(n−1) is equal to or more than 100, the capture number Ndata is determined to be 1024.

Next, the FFT processing part 41 captures the capture number Ndata, which is set by the repeat number setting part 44, of data of the current signal that is detected by the current sensor 31, passes through the filter 33, and A/D converted by the AD-converting part 34 (S13). The FFT processing part 41 performs FFT processing on the captured data (S14), and generates the power spectrum of the current signal.

Next, the representative value acquiring part 42 acquires a representative value S(n) of the power spectrum of the current signal in the predetermined measuring interval in which the FFT processing part 41 performs the FFT (S15).

Next, the arc presence/absence determining part 43 compares the representative value S(n) acquired by the representative value acquiring part 42 with the predetermined threshold K (S16). In the case where the representative value S(n) is greater than the threshold K, the arc is determined as present, and 1 is added to the counter c (S17), and the flow proceeds to S18. On the other hand, in the determination of S16, in the case where the representative value S(n) is less than or equal to the threshold K, the arc is determined as absent. In this case, 1 is not added to the counter c, and the flow proceeds to S18.

In S18, whether the value of the counter n reaches 10, that is, whether n=10, is determined. If n is not 10, 1 is added to the counter n (S19), and the flow returns to S12 to repeat the above processes.

On the other hand, in S18, if n=10, whether the value of the counter c as the number of times that the arc is present is equal to or more than 5 is determined (S20). If the value of the counter c is less than 5, the flow returns to S11 to repeat the above operations.

Further, in S20, if the value of the counter c is equal to or more than 5, the final determination result that the arc is present (arc occurrence) is output (S21). Then, the arc detection processing ends. As described above, in this embodiment, the arc presence/absence determining part 43 outputs the final determination result that the arc is present in the case where there are five times or more of the determination result that the arc is present out of 10 times of the determination on the presence or absence of the arc.

Then, upon receiving the final determination result that the arc is present from the arc presence/absence determining part 43, in order to prevent a fire caused by the arc or the damage of the solar power system 1, the control apparatus of the solar power system 1 cuts off the circuit of solar power system 1.

### Modified Example 1

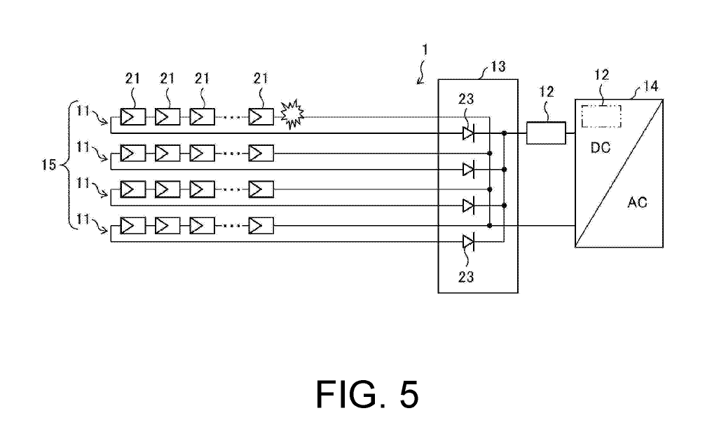

FIG. 5 is a schematic circuit diagram showing a modified example of the solar power system 1 shown in FIG. 1. In the above embodiment, an example in which the arc detecting apparatus 12 is individually provided for each solar cell string 11 is shown. However, the configuration of the arc detecting apparatus 12 is not limited thereto. That is, as shown in FIG. 5, it may also be that only one arc detecting apparatus 12 is provided in the solar power system 1 having a plurality of the solar cell strings 11. In the example of FIG. 5, the arc detecting apparatus 12 is provided at a later stage of the junction box 13, that is, between the junction box 13 and the PCS 14.

Further, as shown in FIG. 5, the arc detecting apparatus 12 may be provided inside the housing of the PCS 14, instead of being provided between the junction box 13 and the PCS 14. In this case, the current signal may be acquired from a current sensor built in the PCS 14. Accordingly, the current sensor 31 can be omitted. Incidentally, the configuration of the solar power system 1 shown in FIG. 5 can also be applied in the following other embodiments.

### Modified Example 2

In the case where the CPU 35 includes an A/D input part having the same function as the A/D converting part 34, the A/D converting part 34 can be omitted. In this case, the signal from the filter 33 may be directly input to the A/D input part of the CPU 35.

### Modified Example 3

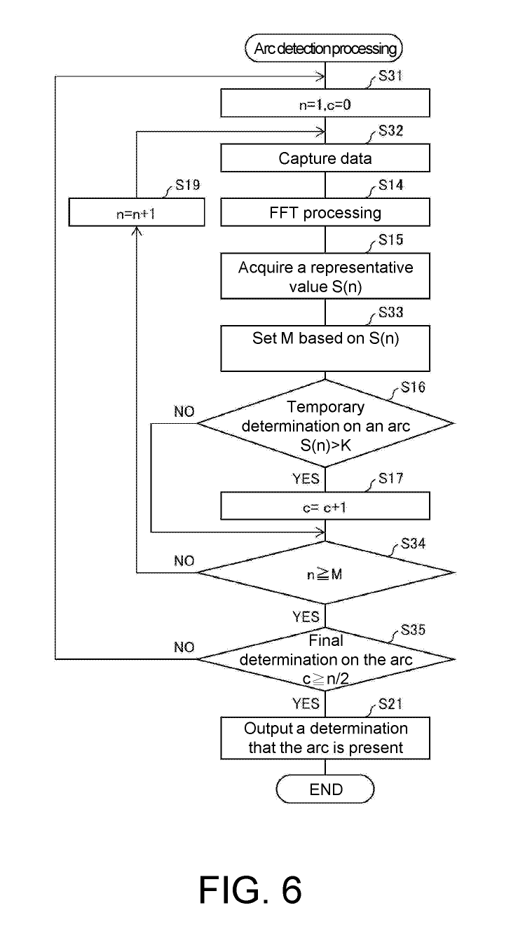

FIG. 6 is a flowchart showing another example of the operation of the arc detecting apparatus 12. In FIG. 6, the arc presence/absence determining part 43 repeats the temporary determination process for the number of times of the repeat number set by the repeat number setting part 44. In FIG. 6, the same step number S is added to the operations same as the operations shown in FIG. 4, and the descriptions of these operations are omitted.

First, as shown in FIG. 6, in the arc detection, the arc presence/absence determining part 43 resets the counter n to the initial value 1 and the counter c to the initial value 0 (S31). Next, the FFT processing part 41 captures the predetermined capture number (for example, 1024) of the data of the current signal detected by the current sensor 31, passing through the filter 33, and A/D-converted by the A/D converting part 34 (S32). The FFT processing part 41 performs FFT processing on the captured data (S14), and generates the power spectrum of the current signal. Next, the representative value acquiring part 42 acquires the representative value S(n) of the power spectrum of the current signal in the predetermined measuring interval in which the FFT processing part 41 performs the FFT (S15).

Next, the repeat number setting part 44 sets a repeat number M of the temporary determination process based on the representative value S(n) currently acquired by the representative value acquiring part 42 (S33). For example, in the case where the representative value S(n) is less than 10, the repeat number M is determined to be 100. In the case where the representative value S(n) is equal to or more than 10 and less than 30, the repeat number M is determined to be 50. In the case where the representative value S(n) is equal to or more than 30 and less than 100, the repeat number M is determined to be 30. If the representative value S(n) is equal to or more than 100, the repeat number M is determined to be 10.

Next, the arc presence/absence determining part 43 compares the representative value S(n) acquired by the representative value acquiring part 42 with the predetermined threshold K (S16). In the case where the representative value S(n) is greater than the threshold K, the arc is determined as present, and 1 is added to the counter c (S17), and the flow proceeds to S34. On the other hand, in the determination of S16, in the case where the representative value S(n) is less than or equal to the threshold K, the arc is determined as absent. In this case, 1 is not added to the counter c, and the flow proceeds to S34.

In S34, whether the value of the counter n reaches the repeat number M, that is, whether n≥M is determined. If it is not that n≥M, 1 is added to the counter n (S19), and the flow returns to S32 to repeat the above processes.

On the other hand, in S34, if n≥M, whether the value of the counter c as the number of times that the arc is present is equal to or more than n/2 is determined (S35). If the value of the counter c is less than n/2, the flow returns to S31 to repeat the above processes.

In addition in S35, if the value of the counter c is equal to or more than n/2, the final determination result that the arc is present is output (S21). Then, the arc detection processing ends. Thus, in this modified example, the arc presence/absence determining part 43 is adapted to output the final determination result that the arc is present in the case where there are n/2 times or more of the determination result that the arc is present out of n times of the temporary determination on the presence/absence of the arc.

### Modified Example 4

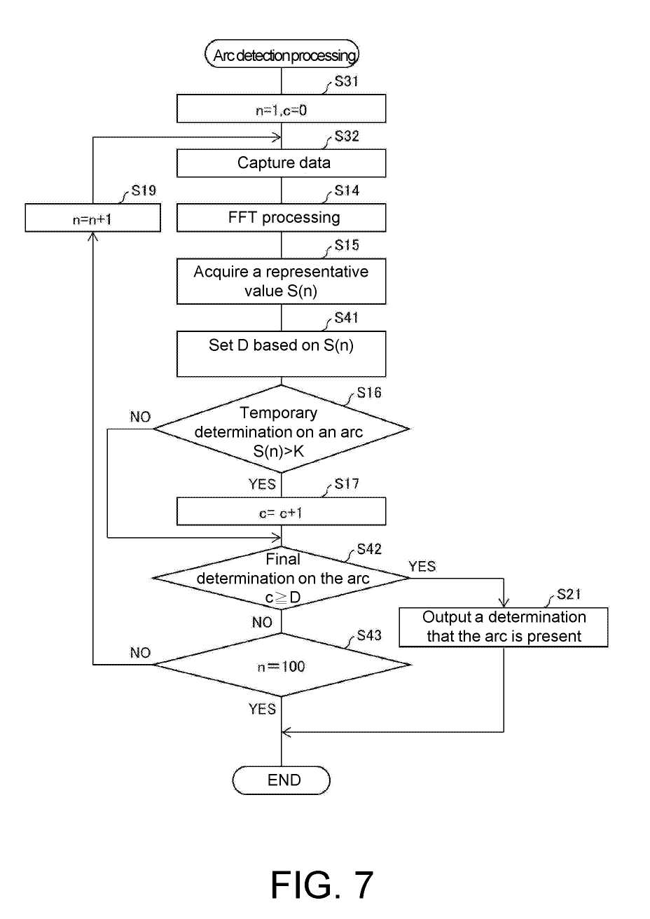

FIG. 7 is a flowchart showing another example of the operation of the arc detecting apparatus 12. In FIG. 7, the arc presence/absence determining part 43 outputs the final determination result that the arc is present to the outside in the case where the temporary determination result that the arc is present repeats the number of times of the repeat number set by the repeat number setting part 44. In FIG. 7, the same step number S is added to the operations same as the operations shown in FIGS. 4 and 6, and the descriptions of these operations are omitted.

First, as shown in FIG. 7, the processing before the processing of acquiring the representative value (S15) is the same as the processing shown in FIG. 6.

After S15, the repeat number setting part 44 sets, based on the representative value S(n) currently acquired by the representative value acquiring part 42, a repeat number D of the temporary determination result that the arc is present (S41). For example, in the case where the representative value S(n) is less than 10, the repeat number D is determined to be 50. In the case where the representative value S(n) is equal to or more than 10 and less than 30, the repeat number D is determined to be 25. Also, in the case where the representative value S(n) is equal to or more than 30 and less than 100, the repeat number D is determined to be 10. Also, in the case where the representative value S(n) is equal to or more than 100, the repeat number D is determined to be 5.

Next, the arc presence/absence determining part 43 compares the representative value S(n) acquired by the representative value acquiring part 42 with the predetermined threshold K (S16). In the case where the representative value S(n) is greater than the threshold K, the arc is determined as present, and 1 is added to the counter c (S17), and the flow proceeds to S42. On the other hand, in the determination of S16, in the case where the representative value S(n) is less than or equal to the threshold K, the arc is determined as absent. In this case, 1 is not added to the counter c, and the flow proceeds to S42.

In S42, whether the value of the counter c reaches the repeat number D, that is, whether c≥D is determined. If c≥D, the flow proceeds to S43. On the other hand, in S42, if c≥D, the final determination result that the arc is present is output (S21). Then, the arc detection processing ends.

In S43, whether the value of the counter n reaches 100, that is, whether n=100 is determined. If n is not 100, 1 is added to the counter n (S19), and the flow returns to S32 to repeat the above processes.

On the other hand, in S43, if n=100, the final determination that the arc is absent is made, and the arc detection processing ends. Thus, in this modified example, the arc presence/absence determining part 43 outputs the final determination result that the arc is present in the case where the temporary determination result that the arc is present exceeds the repeat number D.

### Embodiment 2

Another embodiment of the disclosure will be described below with reference to the drawings. In this embodiment, the solar power system 1 has an arc detecting apparatus 51 in place of the arc detecting apparatus 12.

As shown in FIG. 3(b), when the arc occurs, the power spectrum of the current signal increases. Therefore, the arc detecting apparatus 12 shown in FIG. 2 determines the presence or absence of the arc based on the power spectrum of the current signal. In this case, since the power spectrum is obtained for each frequency, the possibility of erroneous determination can be reduced by excluding the frequencies of the switching noise due to the DC/DC converter, the inverter, etc., from the target of determination.

On the other hand, as shown in FIG. 3(a), when the arc occurs, the amplitude of the current signal increases. Therefore, the arc detecting apparatus 51 according to this embodiment determines the presence or absence of the arc based on the amplitude of the current signal. In this case, since the arithmetic processing, such as FFT, for obtaining the power spectrum is unnecessary, an inexpensive CPU can be used. As a result, the manufacturing cost of the arc detecting apparatus 51 can be reduced.

(Configuration of Arc Detecting Apparatus 51)

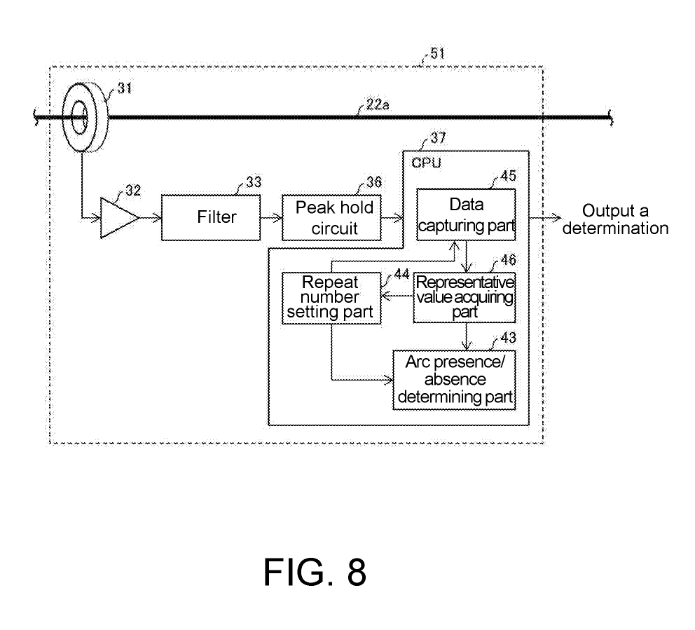

FIG. 8 is a block diagram showing an example of the configuration of the arc detecting apparatus 51 according to this embodiment. Compared with the arc detecting apparatus 12 shown in FIG. 2, the arc detecting apparatus 51 shown in FIG. 8 includes a peak hold circuit 36 in place of the A/D converting part 34, and includes a CPU 37 in place of the CPU 35. Compared with the CPU 35 shown in FIG. 2, the CPU 37 shown in FIG. 8 includes a data capturing part 45 in place of the FFT processing part 41, and includes a representative value acquiring part 46 in place of the representative value acquiring part 42.

The peak hold circuit 36 holds the peak of the current signal passing through the filter 33. The peak hold circuit 36 inputs the held peak value to the CPU 37.

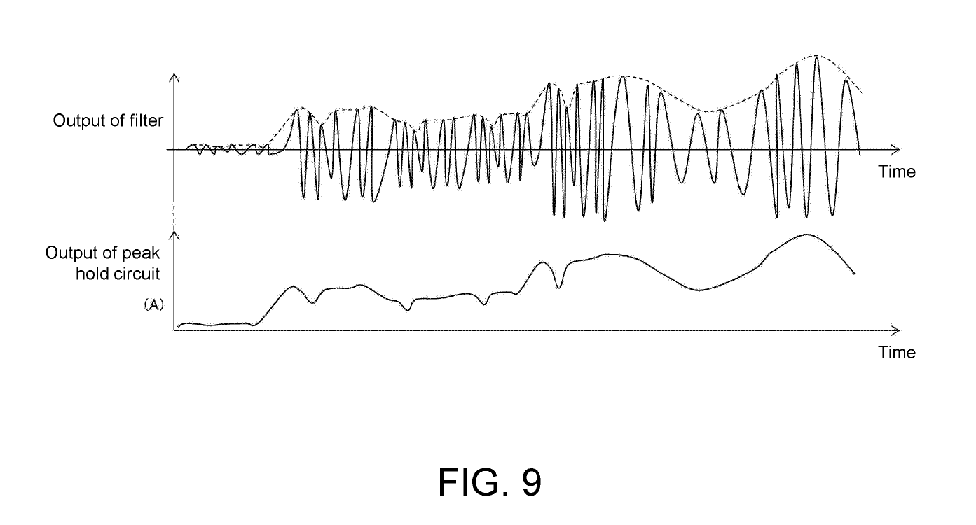

FIG. 9 is a graph showing a temporal change in the current signal output from the filter 33 and the peak value output from the peak hold circuit 36. Referring to FIG. 9, it can be understood that the peak value output by the peak hold circuit 36 corresponds to the amplitude of the current signal.

The data capturing part 45 captures the peak value input from the peak hold circuit 36, and repeats the capturing multiple times. The data capturing part 45 provides the captured peak value set to the representative value acquiring part 46.

The representative value acquiring part 46 obtains the representative value of the amplitude of the current signal based on the peak value set from the data capturing part 45. The representative value acquiring part 46 provides the acquired representative value to the arc presence/absence determining part 43 and the repeat number setting part 44.

As the representative value, various types can be considered. For example, the representative value may be a statistical value, such as an average value, a maximum value, a minimum value, a median value, a mode value, etc., of the amplitude in the predetermined measuring interval (for example, 50 ms).

(Operation of Arc Detecting Apparatus 51)

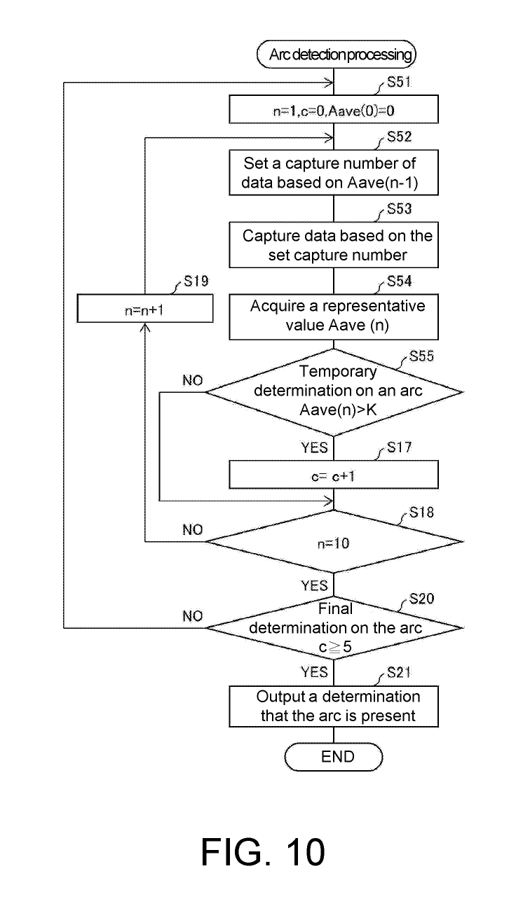

FIG. 10 is a flowchart showing an example of the operation of the arc detecting apparatus 51 of the above configuration. In FIG. 10, the data capturing part 45 repeats data capturing for the number of times of the repeat number set by the repeat number setting part 44. In the example of FIG. 10, a representative value Aave is the average of the amplitude.

Firstly, as shown in FIG. 10, in the arc detection, the arc presence/absence determining part 43 respectively resets the counter n to the initial value 1 and the counter c to the initial value 0, and the repeat number setting part 44 resets the representative value Aave to an initial value Aave(0)=0 (S51).

Next, the repeat number setting part 44 sets the capture number Ndata of data based on the previous (n−1) representative value Aave(n−1) acquired by the representative value acquiring part 46 (S52). For example, in the case where the representative value Aave(n−1) is less than 10, the capture number Ndata is determined to be 8192. Further, in the case where the representative value Aave(n−1) is equal to or more than 10 and less than 30, the capture number Ndata is determined to be 4096. Further, in the case where the representative value Aave(n−1) is equal to or more than 30 and less than 100, the capture number Ndata is determined to be 2048. Further, in the case where the representative value Aave(n−1) is equal to or more than 100, the capture number Ndata is determined to be 1024.

Next, the data capturing part 45 captures peak values of the current signal, which is detected by the current sensor 31, passing through the filter 33, and detected by the peak hold circuit 36, for the capture number Ndata set by the repeat number setting part 44 (S53).

Next, the representative value acquiring part 46 acquires the representative value Aave(n) (amplitude average) of the peak values of the current signal in the predetermined measuring interval of the data capturing part 45 (S54).

Next, the arc presence/absence determining part 43 compares the representative value Aave(n) acquired by the representative value acquiring part 46 with the predetermined threshold K (S55). In the case where the representative value Aave(n) is greater than the threshold K, the arc is temporarily determined as present, and 1 is added to the counter c (S17), and the flow proceeds to S18. On the other hand, in the determination of S55, in the case where the representative value Aave(n) is less than or equal to the threshold K, the arc is determined as absent. In this case, 1 is not added to the counter c, and the flow proceeds to S18. The flow after S18 is the same as FIG. 4.

Referring to FIGS. 4 and 10, it can be understood that, compared with the flowchart shown in FIG. 4, the flowchart shown in FIG. 10 has the changed points that the representative value Aave(n) of the amplitude is used in place of the representative value S(n) of the power spectrum, and the FFT processing (S14) is omitted, while the rest remains the same. Therefore, by applying the changes of the changed points to the flowcharts shown in FIG. 6 and FIG. 7, these flowcharts can be changed to the flowchart of the arc detecting apparatus 51 of this embodiment.

### Modified Example

It should be noted that the peak hold circuit 36 may also be realized as software. In this case, the peak hold circuit 36 may be omitted, and the CPU 35 may further include the A/D input part and include a peak hold part in place of the data capturing part 45. The A/D input part may convert the analog current signal input from the filter 33 into the digital current signal and input the digital current signal to the peak hold part. The peak hold part may capture the digital current signal input from the A/D input part, repeat the capturing multiple times, and hold the peaks of the current signal with respect to the captured current signal set. The peak hold part may provide the held peak values to the representative value acquiring part 46.

### Implementation Example by Software

The control blocks (in particular, the CPU 35, 37) of the arc detecting apparatuses 12 and 51 may be realized by a logic circuit (hardware) formed in an integrated circuit (IC chip), etc., or may be realized by software.

In the latter case, the arc detecting apparatuses 12 and 51 have a computer that executes instructions of a program, which is the software that realizes each function. The computer includes, for example, one or more processors, and includes a computer readable recording medium storing the program. In the computer, the objective of the disclosure is achieved by the processor reading the program from the recording medium and executing the program. As the processor, for example, a CPU can be used. As the recording medium, a tape, a disk, a card, a semiconductor memory, a programmable logic circuit, etc., in addition to a “non-transitory tangible medium” such as a read-only memory (ROM), can be used. Also, the computer may further include a random access memory (RAM), etc., for developing the program. Moreover, the program may be supplied to the computer via an arbitrary transmission medium (a communication network, a broadcast wave, etc.) capable of transmitting the program. It should be noted that an aspect of the disclosure can also be realized in the form of a data signal embedded in a carrier wave, where the program is realized through electronic transmission.

### Additional Notes

Further, in the above embodiments, although the disclosure is applied to the solar power system, the disclosure is not limited thereto. The disclosure can be applied to any power system including a DC power source. Examples of the DC power source, in addition to the solar power apparatus, also include a fuel cell apparatus capable of obtaining electric energy (DC current power) by using hydrogen fuel through electrochemical reaction between hydrogen fuel and oxygen in the air, a storage battery for accumulating electric energy, a power storage apparatus such as a capacitor, etc.

The disclosure is not limited to the above-described embodiments, various modifications are possible within the scope indicated in the claims, and embodiments obtained by appropriately combining technical means respectively disclosed in different embodiments are also included in the technical scope of the disclosure.

According to the configuration and the method, based on the signal strength of the AC current, the repeat number of the processing repeatedly performed to determine the presence or absence of the arc is determined. For example, as the signal strength is high, the repeat number may be decreased. When the signal strength increases, the possibility of erroneously determining noise other than the arc as the noise of the arc is decreased. On the other hand, when the repeat number decreases, the possibility of erroneous determination increases, but the occurrence of the arc can be detected quickly. Therefore, the occurrence of the arc can be quickly detected while the possibility of erroneous determination can be suppressed. That is, the occurrence of the arc can be quickly detected while the frequency of erroneously detecting the occurrence of the arc can be suppressed.

Examples of the signal strength of the AC current include a power spectrum showing a signal strength with respect to frequency, an amplitude of a signal strength with respect to time, etc.

In the arc detecting apparatus, the repeat number may be the number of times that the arc determining part repeatedly acquires data of the AC current to determine the presence or absence of the arc.

In the arc determining apparatus, the arc determining part may make a temporary determination on the presence or absence of the arc based on the AC current, repeatedly make the temporary determination, and make a final determination on the presence or absence of the arc based on the number of times that the arc is temporarily determined as present. In this case, since the presence or absence of the arc is determined in two stages, the accuracy of the determination can be improved.

In the arc detecting apparatus, the repeat number may be the number of times that the arc determining part repeatedly makes the temporary determination.

In the arc detecting apparatus, the repeat number may be the number of times that the arc is temporarily determined as present through the arc determining part repeatedly making the temporary determination.

The arc detecting apparatus may further include a current measuring part which measures the AC current. In this case, the arc determining part can determine the presence or absence of the arc based on the AC current measured by the current measuring part.

What is claimed is:

1. An arc detecting apparatus, comprising:
an arc determining part, which determines presence or absence of an arc based on an AC current contained in a current from a DC power source that generates power or charges and discharges power; and
a repeat number setting part, which sets, based on a signal strength of the AC current, a repeat number of processing that the arc determining part repeatedly performs to determine the presence or absence of the arc.

2. The arc detecting apparatus according to claim 1, wherein the signal strength of the AC current is a power spectrum showing a signal strength with respect to frequency.

3. The arc detecting apparatus according to claim 1, wherein the signal strength of the AC current is an amplitude showing a signal strength with respect to time.

4. The arc detecting apparatus according to claim 1, wherein the repeat number is the number of times that the arc determining part repeatedly acquires data of the AC current to determine the presence or absence of the arc.

5. The arc detecting apparatus according to claim 1, wherein the arc determining part makes a temporary determination on the presence or absence of the arc based on the AC current, repeatedly makes the temporary determination, and makes a final determination on the presence or absence of the arc based on the number of times that the arc is temporarily determined as present.

6. The arc detecting apparatus according to claim 5, wherein the repeat number is the number of times that the arc determining part repeatedly makes the temporary determination.

7. The arc detecting apparatus according to claim 5, wherein the repeat number is the number of times that the arc is temporarily determined as present through the arc determining part repeatedly making the temporary determination.

8. The arc detecting apparatus according to claim 1, further comprising a current measuring part which measures the AC current.

9. A non-transitory computer readable recording medium, recording a control program for causing a computer to serve as the arc detecting apparatus according to claim 1, the control program causing the computer to function as each of the parts.

10. A control method of an arc detecting apparatus, which is a control method of an arc detecting apparatus that detects occurrence of an arc, the control method comprising:
an arc determining step of determining presence or absence of an arc based on an AC current contained in a current from a DC power source that generates power or charges and discharges power; and
a repeat number setting step of setting a repeat number of processing repeatedly performed to determine the presence or absence of the arc in the arc determination step based on a signal strength of the AC current.

11. The arc detecting apparatus according to claim 2, wherein the repeat number is the number of times that the arc determining part repeatedly acquires data of the AC current to determine the presence or absence of the arc.

12. The arc detecting apparatus according to claim 3, wherein the repeat number is the number of times that the arc determining part repeatedly acquires data of the AC current to determine the presence or absence of the arc.

13. The arc detecting apparatus according to claim 2, wherein the arc determining part makes a temporary determination on the presence or absence of the arc based on the AC current, repeatedly makes the temporary determination, and makes a final determination on the presence or absence of the arc based on the number of times that the arc is temporarily determined as present.

14. The arc detecting apparatus according to claim 3, wherein the arc determining part makes a temporary determination on the presence or absence of the arc based on the AC current, repeatedly makes the temporary determination, and makes a final determination on the presence or absence of the arc based on the number of times that the arc is temporarily determined as present.

15. The arc detecting apparatus according to claim 2, further comprising a current measuring part which measures the AC current.

16. The arc detecting apparatus according to claim 3, further comprising a current measuring part which measures the AC current.

17. The arc detecting apparatus according to claim 4, further comprising a current measuring part which measures the AC current.

18. The arc detecting apparatus according to claim 5, further comprising a current measuring part which measures the AC current.

19. The arc detecting apparatus according to claim 6, further comprising a current measuring part which measures the AC current.

20. The arc detecting apparatus according to claim 7, further comprising a current measuring part which measures the AC current.
